(19) United States
(12) Patent Application Publication
(10) Pub. No.: US 2007/0152321 A1
(43) Pub. Date: Jul. 5, 2007

(54) Fluxless heat spreader bonding with cold form solder

(76) Inventors: Wei Shi, Gilbert, AZ (US); Daoqiang Lu, Chandler, AZ (US); Qing Zhou, Chandler, AZ (US); Jiangqi He, Gilber, AZ (US)

Correspondence Address: KONRAD RAYNES & VICTOR, LLP.;ATTN: INT77, 315 SOUTH BEVERLY DRIVE, SUITE 210, BEVERLY HILLS, CA, 90212, US

(21) Appl. No.: 11/323,904

(22) Filed: Dec. 29, 2005

(51) Int. Cl. H01L 23/12; H01L 21/50

(52) U.S. Cl. 257/704; 438/125; 257/706; 257/717; 257/E23.101

(57) ABSTRACT

The formation of electronic assemblies including a heat spreader coupled to at least one die is described. One embodiment relates to a method including positioning a solder on a heat spreader. The method also includes forming a solid state diffusion bond between the solder and the heat spreader. The solid state diffusion bonded solder and heat spreader are positioned on a die and heated to a temperature sufficient to melt the solder and form a bond between the solder and the die, in the absence of a flux. Other embodiments are described and claimed.

### RELATED ART

Integrated circuits may be formed on semiconductor wafers that are formed from materials such as silicon. The semiconductor wafers are processed to form various electronic devices thereon. The wafers are diced into semiconductor chips (also known as dies), which may then be attached to a package substrate using a variety of known methods. In one known method for attaching a die to a substrate, the die may have solder bump contacts which are electrically coupled to the integrated circuit. The solder bump contacts extend onto the contact pads of a package substrate, and are typically attached in a thermal reflow process. Electronic signals may be provided through the solder bump contacts to and from the integrated circuit.

Operation of the integrated circuit generates heat in the device. As the internal circuitry operates at increased clock frequencies and/or higher power levels, the amount of heat generated may rise to levels that are unacceptable unless some of the heat can be removed from the device. Heat is conducted to a surface of the die, and should be conducted or convected away to maintain the temperature of the integrated circuit below a predetermined level for purposes of maintaining functional integrity of the integrated circuit.

One way to conduct heat from an integrated circuit die is through the use of a heat spreader, which may be positioned above the die and thermally coupled to the die through a thermal interface material. Materials such as certain solders may be used as thermal interface material and to couple the heat spreader to the die. A flux is typically applied to at least one of the surfaces to be joined and the surfaces brought into contact. The flux acts to remove the oxide on the solder surfaces to facilitate solder wetting. A heating operation at a temperature greater than the melting point of the solder is carried out, and a solder connection is made between the die and the heat spreader. The joined package is then cooled and the solder solidified.

### BRIEF DESCRIPTION OF THE DRAWINGS

Embodiments are described by way of example, with reference to the accompanying drawings, which are not drawn to scale, wherein:

FIG. 1 is a flow chart of certain operations for forming an assembly including a heat spreader bonded to at least one die through a solder, in accordance with certain embodiments;

FIG. 2 illustrates an solder undergoing an oxide removal operation in accordance with certain embodiments;

FIG. 3 illustrates a solder positioned on a heat spreader, in accordance with certain embodiments;

FIG. 4 illustrates a solder bonded to a heat spreader and including an oxide layer thereon, in accordance with certain embodiments;

FIG. 5 illustrates a solder bonded to a heat spreader and undergoing an oxide removal operation, in accordance with certain embodiments;

FIG. 6 illustrates a solder bonded to a heat spreader and having a gold layer thereon, in accordance with certain embodiments;

FIG. 7 illustrates a solder bonded to a heat spreader and positioned over a substrate having a plurality of dies thereon, in accordance with certain embodiments;

FIG. 8 illustrates a solder and heat spreader positioned on a substrate having a plurality of dies thereon, in accordance with certain embodiments;

FIG. 9 illustrates a heat spreader joined to a plurality of dies and coupled to a substrate, in accordance with certain embodiments.

FIG. 10 illustrates a heat spreader joined to a plurality of dies having differing thicknesses, in accordance with certain embodiments;

FIG. 11 illustrates a flow chart of certain operations for forming an assembly including a heat spreader bonded to at least one die on a substrate, in accordance with certain embodiments; and

FIG. 12 illustrates an electronic system arrangement in which certain embodiments may find application.

### DETAILED DESCRIPTION

The use of flux in attaching a heat spreader to a die can lead to certain problems. The flux can cause voids in the solder thermal interface material (TIM) layer between a die and a heat spreader, and thus degrades the thermal performance and the reliability of the TIM layer joint. The use of a flux typically results in flux residue including organic compounds, present in and around the solder TIM joint. In certain types of assemblies, a heat spreader may also act as a lid over a die on a substrate. As a result, after the solder bond between the die and heat spreader lid is made, it is difficult or not possible to remove flux residue because the joint between the die and heat spreader is covered by the heat spreader and not accessible.

Certain embodiments relate to the formation of electronic assemblies, including fluxless attach processes for forming connections between one or more dies and a heat spreader.

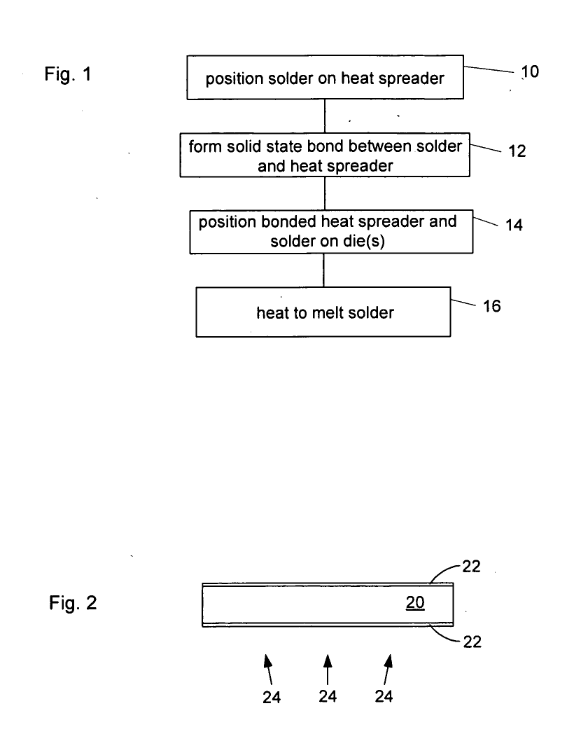

FIG. 1 is a flow chart showing a number of operations in accordance with certain embodiments for a fluxless bonding process. Box 10 is positioning a solder on a surface of a heat spreader. The heat spreader is adapted to transmit heat away from one or more dies to be positioned under the heat spreader. Box 12 is forming a solid state bond between the solder and the heat spreader. By solid state bond it is meant that the bond is formed at a temperature below the melting point of the materials and a solid state diffusion process occurs. A flux is not needed to make the bond between the solder and the heat spreader.

Box 14 is positioning the bonded heat spreader and solder on one or more dies to be bonded thereto. The die(s) may be positioned on a substrate. In addition, the heat spreader may have a shape that permits it to act as a lid so that the lid covers the die(s) on the substrate. Box 16 is heating the assembly so that the solder melts and forms a bond between the heat spreader and the die(s). The heating may in certain embodiments be carried out in a nitrogen atmosphere to inhibit oxidation of metals in the assembly.

FIG. 2-9 illustrate aspects of a fluxless bonding method for bonding a heat spreader to one or more dies in accordance with certain embodiments. As illustrated in FIG. 2, a solder 20 may be shaped into a preform that is to be placed onto a heat spreader and then joined to one or more dies. The solder 20 may be formed from a variety of solders, which generally have a melting point of less than about 300° C. Examples of materials which may be used in the solder include, but are not limited to, indium (In) and tin (Sn). The solder 20 may have an oxide layer 22 thereon, which will tend to interfere with the formation of a good bond between the various layers. As a result, the solder 20 may be processed to remove the oxide layer 22. In certain embodiments, the oxide layer 22 is removed by etching with layer with a plasma 24.

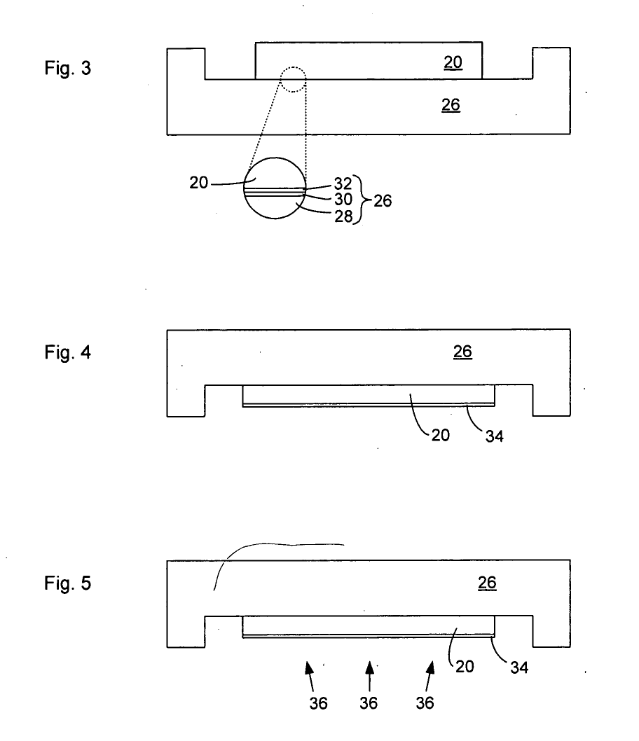

FIG. 3 illustrates the solder 20 with the etched side positioned on the heat spreader 26. The heat spreader 26 may be formed from a variety of materials, including, but not limited to, copper (Cu), and in certain embodiments may include one or more layers formed thereon. The overall thickness of the heat spreader 26 may in certain embodiments be about 1 to 3 mm. As illustrated in FIG. 3, the heat spreader 26 includes a base layer 28 and two thin layers 30 and 32 thereon. In certain embodiments, the base layer 28 comprises copper, the layer 30 comprises nickel, and the layer 32 comprises gold. The nickel layer acts as a wetting layer for the solder TIM, and the gold layer acts to protect the nickel layer from oxidation. In certain embodiments, the nickel layer is formed to a thickness in the range of about 3-7 μm and the gold layer is formed to a thickness in the range of about 0.05-0.2 μm.

FIG. 4 illustrates the solder 20 after it has been bonded to the heat spreader 26 in a solid state diffusion bonding process. In certain embodiments, the solid state bonding process is a cold forming process in which the solder 20 and heat spreader 26 are positioned together and a small roller is moved across the surface of the solder 20 at a suitable pressure and temperature. The rolling will thin the solder 20 and the pressure and temperature will act to form a solid state diffusion bond between the solder 20 and the heat spreader 26. A variety of temperatures and pressures may be used. In general, as the temperature increases, the rate of solid state diffusion will increase. Similarly, in general, as the pressure increases, the rate of solid state diffusion will increase. Certain embodiments utilize a rolling pressure in the range of from about 20 lb to 100 lb, and a rolling temperature of from about 30° C. to 60° C., in a nitrogen atmosphere or vacuum. In certain embodiments, the heat spreader is preheated to about 50° C. to 60° C. The rolling time may in certain embodiments range from about 5 seconds to about 5 minutes. No flux is used in the cold forming process. In certain embodiments, the solder 20 may be up to about 200 μm thick. In one such embodiment, the solder 20 may be about 150 μm thick prior to the cold forming operation, and about 100 μm thick after the cold forming operation.

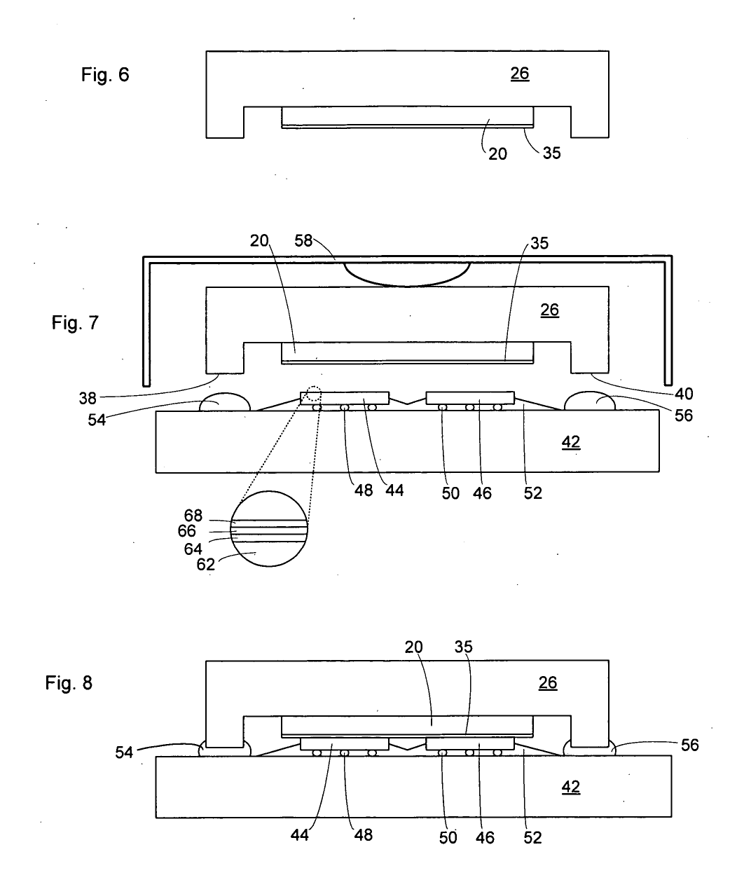

As illustrated in FIGS. 4-5, after the solder 20 is bonded to the heat spreader 26, an oxide layer 34 may be located on the non-bonded surface of the solder 20. The oxide layer 34 may then be removed from the solder 20. In certain embodiments, the oxide layer 34 is etched from the solder 20 using a suitable plasma 36. As illustrated in FIG. 6, a layer 35 formed from, for example, gold, may be formed on the plasma etched surface of the cold formed solder 20. The layer 35 may act to protect the solder from oxidation and also may act to promote adhesion between the solder 20 and another surface.

FIG. 7 illustrates the positioning of the bonded heat spreader 26 and cold formed solder 20 relative to a substrate 42, which includes a plurality of semiconductor dies 44, 46 thereon. The dies 44, 46 are electrically coupled to the substrate, for example, using bumps 48, 50, and a suitable die underfill material 52 may be present. A sealant material 54, 56, which may in certain embodiments be formed from a polymer, is also formed on the substrate 42 surface. As illustrated in FIG. 7, the heat spreader 26 may include leg regions 38, 40 that will be positioned on the sealant 54, 56 to form a cap over the dies 44, 46 coupled to the substrate 42. A suitable clip mechanism 58 may be used to hold the heat spreader 26 and solder 20 and apply pressure to hold the heat spreader 26 and solder 20 to the substrate 42 during solder reflow. In certain embodiments, the clip 58 is coupled to a carrier (not shown) which holds the substrate 42.

The dies 44, 46 may in certain embodiments have a flip-chip configuration with an active die surface facing the substrate 42 and a back side surface facing the solder 20. The back side surface of the dies 44, 46 may include a suitable back side metallization (BSM) that protects the dies 44, 46 and promotes the bonding of the dies 44, 46 to the solder 20. In certain embodiments, the back side metallization includes one or more suitable metal layers. For example, as illustrated in FIG. 7, the back side metallization of the die 48 may include three metal layers 64, 66, 68. In certain embodiments, the layers 64, 66, and 68 may be formed from include layers of titanium, nickel or nickel vanadium (NiV), and gold, respectively, on silicon region 62. In one embodiment, the layer 64 is a Ti layer having a thickness of about 0.1 μm, the layer 66 is a NiV layer having a thickness of about 0.4 μm, and the layer 68 is a Au layer having a thickness of about 0.1 μm.

FIG. 8 illustrates the bonded heat spreader 26 and cold formed solder 20 positioned on the dies 44, 46 on the substrate 42. The leg regions 38, 40 of the heat spreader 26 are positioned on the sealant regions 54, 56. No flux needs to be placed onto the surfaces to be soldered. The assembly is then heated to a temperature to melt the solder and form a bond between the heat spreader 26 and dies 44, 46. In certain embodiments, the heating may take place in a continuous reflow oven and the heating may be conducted in a substantially oxygen free atmosphere (for example, nitrogen with no greater than 10 ppm (parts per million) oxygen) at a temperature of about 10-25 degrees Celsius greater than the melting point of the solder 20.

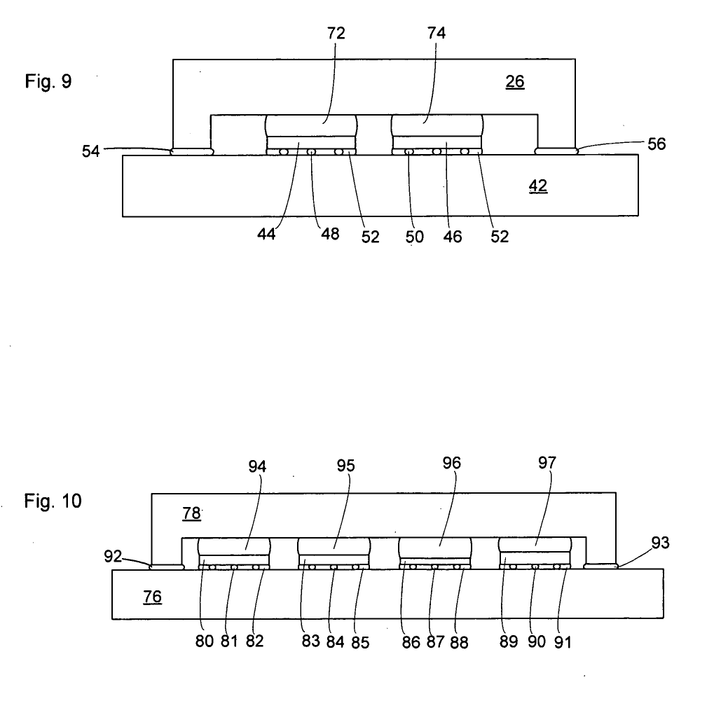

FIG. 9 illustrates an assembly after the heating operation including joints 72, 74 positioned between the dies 44, 46 and the heat spreader 26. The joints 72, 74 include the material from the solder 20 and from at least some of the various layer(s) of the heat spreader 26 and the back side metallization of the dies 44, 46. Depending on the elements used in the various layers, the finished joint may include a number of layers, including various combinations of the elements used. Some of the combinations may comprise alloys and some may comprise intermetallic compounds. For example, where indium or an indium alloy is used for the solder, and one or more gold layers are used, the joint will in certain embodiments include one or more alloys and one or more indium gold intermetallic compounds. As no flux needs to be used, there will be no organic flux residue in the joint. By eliminating the flux, a void free joint may be obtained.

FIG. 10 illustrates an assembly in accordance with certain embodiments, in which a plurality of dies 80, 83, 86, 89 of varying thicknesses are used. The dies are coupled to a substrate 76 through a connection such as solder bumps 81, 84, 87, 90. A die underfill material 82, 85, 88, 91 is also present. A heat spreader 78 is coupled to joint regions 94, 95, 96, 97 and coupled to the substrate 76 through sealant regions 92, 93. As in FIG. 10, die 86 is thinner than dies 80, 83, and 89. Die 89 is thicker than dies 80, 83, and 86. By varying the thickness of various regions of the solder in accordance with the positions of the dies, the difference in thickness can be accounted for so that the final assembly will be substantially planar. Other processing operations for forming the assembly may be similar to those described above. As a result of the differing thickness of the solder, the joints will have varying thicknesses. Joint 96 is thicker than the joints 94, 95, and 97. Joint 97 is thinner than the joints 94, 95, and 96. In addition, embodiments may also be adapted to take into account die or substrate warpages and yield a substantially planar assembly.

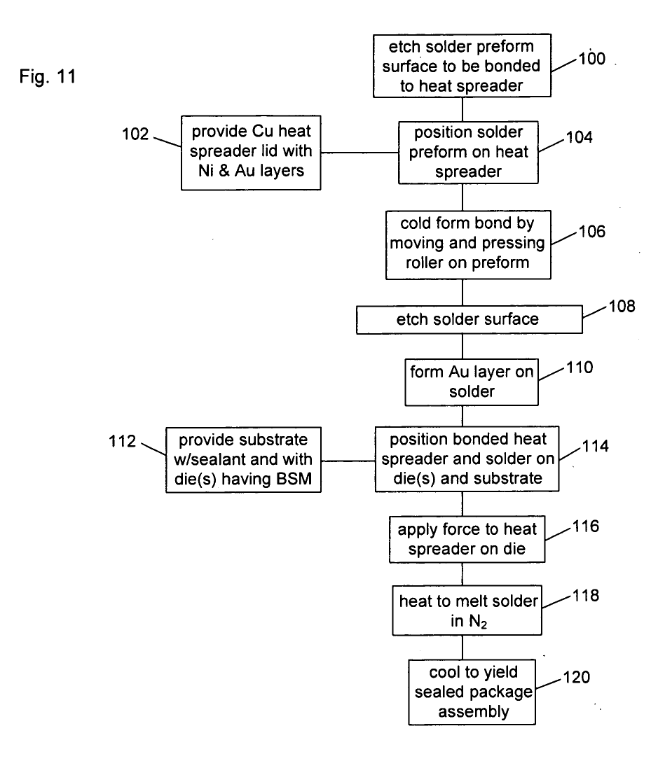

FIG. 11 illustrates a flow chart describing a method for forming an assembly in accordance with certain embodiments. Box 100 is etching a solder preform to remove oxide therefrom. Box 102 is providing a heat spreader in a lid shape that is formed from copper with layers comprising nickel and gold thereon. Box 104 is positioning the solder preform on the heat spreader. Box 106 is forming a cold form bond by cold forming the solder preform to obtain a solid state diffusion bond between the solder and the heat spreader. No flux is used for making the bond between the solder and heat spreader. Box 108 is etching the non-bonded side of the solder to remove oxide therefrom. Box 110 is forming a gold layer on the etched solder.

Box 112 is providing a substrate with at least one flip chip die thereon, the flip chip die having a back side metallization thereon, the substrate including a sealant region thereon. Box 114 is positioning the bonded heat spreader and solder on the die(s) and substrate, with end portions of the heat spreader positioned on the sealant region, and with the solder cold form on the die(s). Box 116 is applying a force to the press the solder onto the die(s). Box 118 is heating in a nitrogen atmosphere at a temperature sufficient to melt the solder. No flux is used in the joining operation. Box 120 is cooling the assembly to yield an assembly including a sealed package with the heat spreader bonded to the die(s) through solder joint(s). The joint between the heat spreader and the die(s) may include no voids and no flux residue, thus increasing the thermal performance and reliability of the assembly.

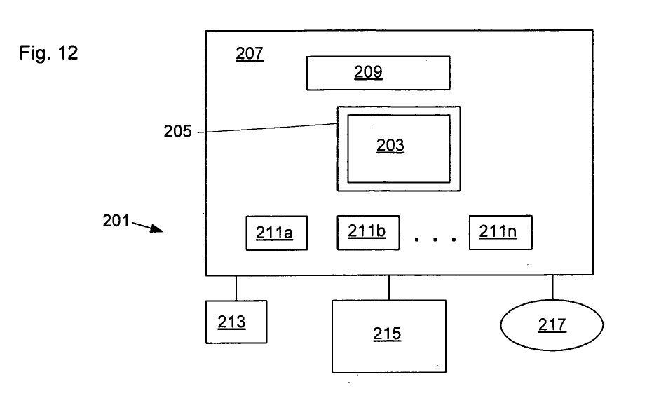

Assemblies including a substrate and chip joined together as described in embodiment above may find application in a variety of electronic components. FIG. 12 schematically illustrates one example of an electronic system environment in which aspects of described embodiments may be embodied. Other embodiments need not include all of the features specified in FIG. 12, and may include alternative features not specified in FIG. 12.

The system 201 of FIG. 12 may include at least one central processing unit (CPU) 203. The CPU 203, also referred to as a microprocessor, may be a chip which is attached to an integrated circuit package substrate 205, which is then coupled to a printed circuit board 207, which in this embodiment, may be a motherboard. The CPU 203 on the package substrate 205 is an example of an electronic device assembly that may have a structure formed in accordance with embodiments such as described above. A variety of other system components, including, but not limited to memory and other components discussed below, may also include assembly structures formed in accordance with the embodiments described above.

The system 201 further may further include memory 209 and one or more controllers 211a, 211b . . . 211n, which are also disposed on the motherboard 207. The motherboard 207 may be a single layer or multi-layered board which has a plurality of conductive lines that provide communication between the circuits in the package 205 and other components mounted to the board 207. Alternatively, one or more of the CPU 203, memory 209 and controllers 211a, 211b . . . 211n may be disposed on other cards such as daughter cards or expansion cards. The CPU 203, memory 209 and controllers 211a, 211b . . . 211n may each be seated in individual sockets or may be connected directly to a printed circuit board. A display 215 may also be included.

Any suitable operating system and various applications execute on the CPU 203 and reside in the memory 209. The content residing in memory 209 may be cached in accordance with known caching techniques. Programs and data in memory 209 may be swapped into storage 213 as part of memory management operations. The system 201 may comprise any suitable computing device, including, but not limited to, a mainframe, server, personal computer, workstation, laptop, handheld computer, handheld gaming device, handheld entertainment device (for example, MP3 (moving picture experts group layer-3 audio) player), PDA (personal digital assistant) telephony device (wireless or wired), network appliance, virtualization device, storage controller, network controller, router, etc.

The controllers 211a, 211b . . . 211n may include one or more of a system controller, peripheral controller, memory controller, hub controller, I/O (input/output) bus controller, video controller, network controller, storage controller, communications controller, etc. For example, a storage controller can control the reading of data from and the writing of data to the storage 213 in accordance with a storage protocol layer. The storage protocol of the layer may be any of a number of known storage protocols. Data being written to or read from the storage 213 may be cached in accordance with known caching techniques. A network controller can include one or more protocol layers to send and receive network packets to and from remote devices over a network 217. The network 217 may comprise a Local Area Network (LAN), the Internet, a Wide Area Network (WAN), Storage Area Network (SAN), etc. Embodiments may be configured to transmit and receive data over a wireless network or connection. In certain embodiments, the network controller and various protocol layers may employ the Ethernet protocol over unshielded twisted pair cable, token ring protocol, Fibre Channel protocol, etc., or any other suitable network communication protocol.

While certain exemplary embodiments have been described above and shown in the accompanying drawings, it is to be understood that such embodiments are merely illustrative and not restrictive, and that embodiments are not restricted to the specific constructions and arrangements shown and described since modifications may occur to those having ordinary skill in the art.

1. (canceled)

2. The method of claim 3, wherein the forming a solid state diffusion bond between the solder and the heat spreader includes moving a roller along the solder on the heat spreader at a temperature below the melting point of the solder.

3. A method comprising:
positioning a solder on a heat spreader surface;
forming a solid state diffusion bond between the solder and the heat spreader;
positioning the solid state diffusion bonded solder and heat spreader on a die;
heating the solder to a temperature sufficient to melt the solder and form a bond between the heat spreader and the die, in the absence of a flux; and
removing oxide from a first surface of the solder prior to the positioning a solder on a heat spreader surface.

4. The method of claim 3, further comprising removing oxide from a second surface of the solder, after the forming a solid state diffusion bond between the solder and the heat spreader, and prior to the positioning the solid state diffusion bonded solder and heat spreader on a die.

5. A method as in claim 3, wherein the heat spreader surface includes a layer of gold, and wherein the positioning the solder on the heat spreader surface comprises positioning the solder on the layer of gold.

6. A method comprising:
positioning a solder on a heat spreader surface;
forming a solid state diffusion bond between the solder and the heat spreader;
positioning the solid state diffusion bonded solder and heat spreader on a die;
heating the solder to a temperature sufficient to melt the solder and form a bond between the heat spreader and the die, in the absence of a flux; and
plasma etching a first surface of the solder prior to the positioning a solder on a heat spreader surface, and then positioning the first surface on the heat spreader surface.

7. The method of claim 3, wherein the heat spreader comprises copper having a nickel layer and a gold layer formed thereon, wherein the nickel layer is between the copper and the gold layer, and wherein the positioning the solder on the heat spreader surface comprises positioning the solder on the gold layer.

8. The method of claim 4, further comprising forming a layer of gold on the bonded solder after the removing oxide from a second surface of the solder, and prior to the positioning the bonded solder and heat spreader on the die.

9. The method of claim 3, wherein the die includes a gold layer, and wherein the positioning the bonded solder and heat spreader on the die comprises positioning the bonded solder and heat spreader on the gold layer.

10. The method of claim 3, wherein the positioning the bonded solder and heat spreader on the die comprises applying a force to the heat spreader.

11. The method of claim 3, wherein the die is coupled to a substrate, and wherein the positioning the bonded solder and heat spreader on a die also includes positioning a portion of the heat spreader on a sealant material positioned on the substrate.

12. The method of claim 3, wherein the heating comprises heating in an atmosphere comprising nitrogen.

13. A method comprising:
etching a first surface of a solder;
positioning the etched first surface of the solder on a heat spreader;
forming a solid state diffusion bond between the solder and the heat spreader, so that the first surface of the solder is bonded to the heat spreader;
after the forming a solid state diffusion bond, etching a second surface of the solder;
positioning the etched second surface of the solder on at least one die; and
heating the solder to a temperature sufficient to melt the solder and form a bond between the heat spreader and the at least one die, in the absence of a flux.

14. The method of claim 13, wherein the die is coupled to a substrate, further comprising coupling an outer portion of the heat spreader to the die through a sealant material.

15. The method of claim 13, further comprising curing the sealant material during the heating the solder perform.

16. The method of claim 13, wherein the positioning the etched second surface of the solder on at least one die comprises positioning the etched second surface of the solder on a plurality of dies, the dies having different thicknesses.

17. The method of claim 13, wherein the solder comprises at least one material selected from the group consisting of indium and tin.

18-24. (canceled)

25. The method of claim 6, wherein the forming a solid state diffusion bond between the solder and the heat spreader includes forming the bond at a temperature below the melting point of the solder.

26. The method of claim 6, wherein the heat spreader comprises copper having a nickel layer and a gold layer formed thereon, wherein the nickel layer is between the copper and the gold layer, and wherein the positioning the solder on the heat spreader surface comprises positioning the solder on the gold layer.

27. The method of claim 6, further comprising plasma etching a second surface of the solder, after the forming a solid state diffusion bond between the solder and the heat spreader, and prior to the positioning the solid state diffusion bonded solder and heat spreader on a die.

28. The method of claim 27, further comprising forming a layer of gold on the solder after the plasma etching a second surface.

29. A method comprising:
positioning a solder on a heat spreader;
forming a solid state diffusion bond between the solder and the heat spreader;
etching a surface of the solder after the forming a bond between the solder and the heat spreader; and
after the etching, coupling the bonded solder and heat spreader to at least one die, wherein the etched surface of the solder is positioned between the at least one die and the heat spreader, wherein the coupling is carried out using a method including heating the solder to a temperature sufficient to melt the solder and form a bond between the heat spreader and the at least one die, in the absence of a flux.

30. The method of claim 29, further comprising etching a surface of the solder prior to the positioning a solder of a heat spreader, wherein the positioning a solder on the heat spreader includes positioning the etched surface on the heat spreader.

31. The method of claim 29, further comprising forming a layer of gold on the etched surface of the solder prior to the coupling the bonded solder and heat spreader to the at least one die.

32. The method of claim 31, wherein the at least one die includes a layer of gold thereon.
